(19) United States
(12) Patent Application Publication
(10) Pub. No.: US 2025/0116941 A1
(43) Pub. Date: Apr. 10, 2025

(54) STITCHING METHOD FOR EXPOSURE PROCESS

(71) Applicants: Powerchip Semiconductor Manufacturing Corporation, Hsinchu (TW); AP Memory Technology Corporation, Hsinchu County (TW)

(72) Inventors: Shou-Zen Chang, Hsinchu City (TW); Chun-Lin Lu, Hsinchu City (TW); Cheng-Shu Ho, Hsinchu (TW); Kuo-Wei Liu, Hsinchu (TW); Kee-Wei Chung, Hsinchu County (TW); Ru-Yi Cai, Hsinchu County (TW)

(73) Assignees: Powerchip Semiconductor Manufacturing Corporation, Hsinchu (TW); AP Memory Technology Corporation, Hsinchu County (TW)

(21) Appl. No.: 18/509,259

(22) Filed: Nov. 14, 2023

(30) Foreign Application Priority Data
Oct. 5, 2023 (TW) 112138323

(51) Int. Cl. G03F 7/00; G03F 1/42

(52) U.S. Cl. CPC G03F 7/70475; G03F 1/42

(57) ABSTRACT

A stitching method for an exposure process includes following steps. A wafer is provided. The wafer includes interposer regions, each of which includes a logic chip region, a first memory chip region, and a second memory chip region. The logic chip region is located between the first and second memory chip regions. A photoresist layer is formed on the wafer. First exposure processes are performed on the photoresist layer by applying a first photomask to form first shot regions in the photoresist layer. Second exposure processes are performed on the photoresist layer by applying a second photomask to form second shot regions in the photoresist layer. The first shot regions and the second shot regions are arranged alternately in a first direction. The first shot regions and the second shot regions are overlapped to form stitching regions, each of which is not located in the logic chip region.

### CROSS-REFERENCE TO RELATED APPLICATION

This application claims the priority benefit of Taiwan application serial no. 112138323, filed on Oct. 5, 2023. The entirety of the above-mentioned patent application is hereby incorporated by reference herein and made a part of this specification.

### BACKGROUND

### Technical Field

The disclosure relates to a semiconductor process; more particularly, the disclosure relates to a stitching method for an exposure process.

### Description of Related Art

At present, a semiconductor packaging methodology has been advanced, where semiconductor chips are vertically stacked or horizontally arranged upon an interposer. Due to the larger size of the interposer compared to that of a photomask, it is imperative to employ lithography stitching techniques for forming circuit patterns on the interposer. However, if a process window for the stitching process is constrained, a photoresist pattern located at a stitching junction is susceptible to deformation, thereby impeding the attainment of the anticipated photoresist pattern.

### SUMMARY

The disclosure provides a stitching method for an exposure process, which may effectively improve a process window of a stitching process.

In an embodiment of the disclosure, a stitching method for an exposure process includes following steps. A wafer is provided. The wafer includes a plurality of interposer regions, and each of the interposer regions includes a logic chip region, a first memory chip region, and a second memory chip region. The logic chip region is located between the first memory chip region and the second memory chip region. A photoresist layer is formed on the wafer. A plurality of first exposure processes are performed on the photoresist layer by applying a first photomask to form a plurality of first shot regions in the photoresist layer. A plurality of second exposure processes are performed on the photoresist layer by applying a second photomask to form a plurality of second shot regions in the photoresist layer. The first shot regions and the second shot regions are arranged alternately in a first direction. The first shot regions and the second shot regions are overlapped to form a plurality of stitching regions, and each of the stitching regions is not located in the logic chip region.

According to an embodiment of the disclosure, in the stitching method, the logic chip region in each of the interposer regions may be exclusively located in a corresponding first shot region of the first shot regions.

According to an embodiment of the disclosure, in the stitching method, a size of each of the first shot regions may be equal to or greater than a size of each of the second shot regions.

According to an embodiment of the disclosure, in the stitching method, the first memory chip region in each of the interposer regions may be located in a corresponding second shot region of the second shot regions.

According to an embodiment of the disclosure, in the stitching method, the first memory chip region in each of the interposer regions may be further located in a corresponding first shot region of the first shot regions.

According to an embodiment of the disclosure, in the stitching method, the second memory chip region in each of the interposer regions may be located in a corresponding second shot region of the second shot regions.

According to an embodiment of the disclosure, in the stitching method, the second memory chip region in each of the interposer regions may be further located in a corresponding first shot region of the first shot regions.

According to an embodiment of the disclosure, in the stitching method, each of the first shot regions may be overlapped with the logic chip region in a corresponding interposer region of the interposer regions.

According to an embodiment of the disclosure, in the stitching method, the each of the first shot region may be further overlapped with the first memory chip region and the second memory chip region in the corresponding interposer region.

According to an embodiment of the disclosure, in the stitching method, each of the second shot regions may be overlapped with the first memory chip region in one of two adjacent interposer regions of the interposer regions and the second memory chip region in the other of the two adjacent interposer regions.

According to an embodiment of the disclosure, in the stitching method, two of the stitching regions may be located in each of the interposer regions.

According to an embodiment of the disclosure, in the stitching method, one of the two stitching regions may be located between the logic chip region and the first memory chip region in a corresponding interposer region of the interposer regions.

According to an embodiment of the disclosure, in the stitching method, the other of the two stitching regions may be located between the logic chip region and the second memory chip region in the corresponding interposer region.

According to an embodiment of the disclosure, in the stitching method, one of the two stitching regions may be overlapped with the first memory chip region in the corresponding interposer region.

According to an embodiment of the disclosure, in the stitching method, the other of the two stitching regions may be overlapped with the second memory chip region in the corresponding interposer region.

According to an embodiment of the disclosure, in the stitching method, the wafer may further include a plurality of first scribed line regions and a plurality of second scribed line regions. The first scribed line regions may extend in a first direction and may be arranged in a second direction. The second scribed line regions may extend in the second direction and may be arranged in the first direction. The first direction may intersect the second direction. The first scribed line regions may intersect the second scribed line regions.

According to an embodiment of the disclosure, in the stitching method, the first scribed line regions and the second scribed line regions may define the interposer regions.

According to an embodiment of the disclosure, in the stitching method, the first direction may be perpendicular to the second direction.

According to an embodiment of the disclosure, in the stitching method, each of the first shot regions may be overlapped with a corresponding first scribed line region of the first scribed line regions.

According to an embodiment of the disclosure, in the stitching method, each of the second shot regions may be overlapped with a corresponding first scribed line region of the first scribed line regions and a corresponding second scribed line region of the second scribed line regions.

In view of the above, in the stitching method for the exposure process as provided in one or more embodiments of the disclosure, since the stitching regions are not located in the logic chip regions with complex circuit patterns, the process window of the stitching process may be effectively improved. As such, after a development process is performed on the photoresist layer, the anticipated photoresist pattern may be obtained.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 is a schematic top view of a wafer according to some embodiments of the disclosure.

FIG. 2 is a schematic view of an exposure process according to some embodiments of the disclosure.

FIG. 3 is a schematic view of an exposure process according to other embodiments of the disclosure.

FIG. 4 is a schematic view of an exposure process according to other embodiments of the disclosure.

### DESCRIPTION OF THE EMBODIMENTS

Reference will now be made in detail to the exemplary embodiments of the disclosure, examples of which are illustrated in the accompanying drawings. Whenever possible, the same reference numerals are used to represent the same drawings or similar parts in the accompanying and description, and the description of the same technical content is omitted. The description of the omitted part may be derived from the previous embodiment and will not be repeated in the following embodiments.

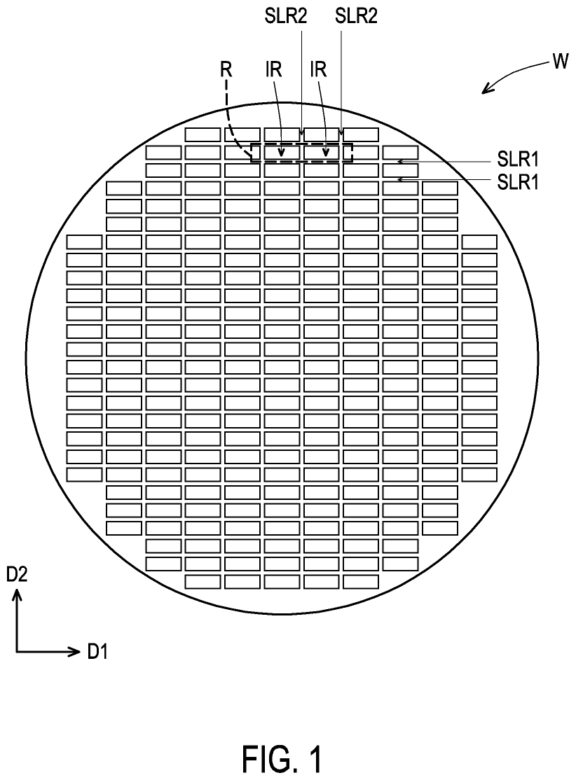

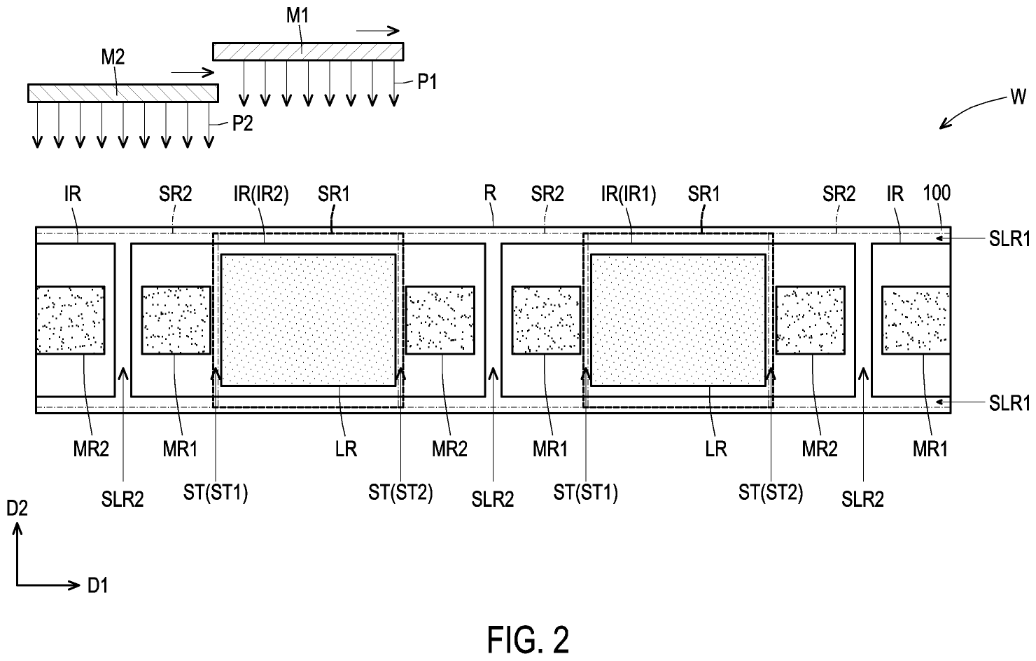

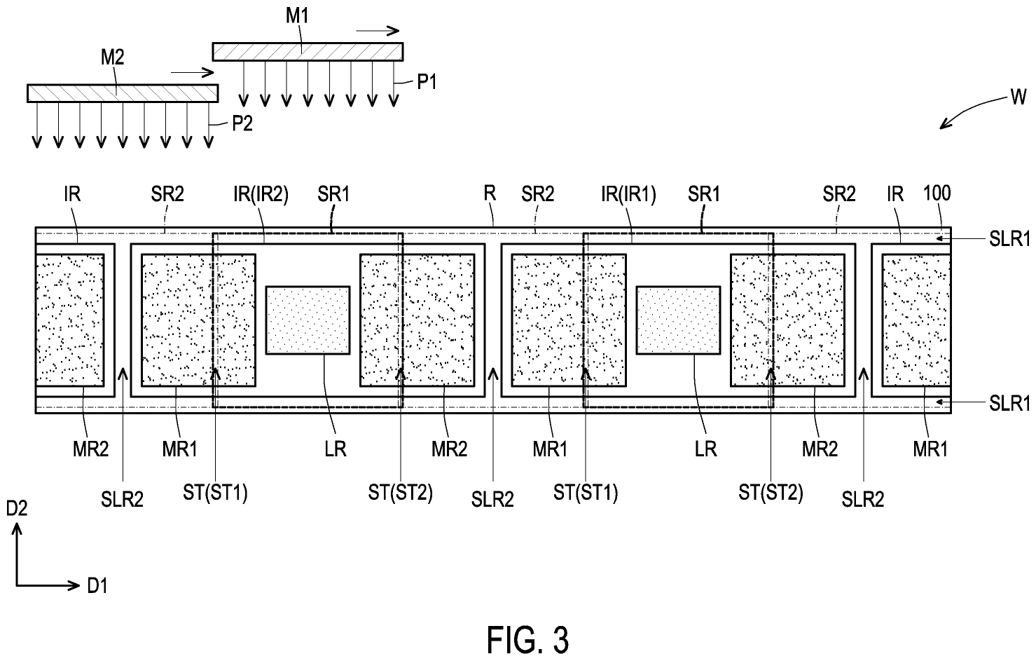

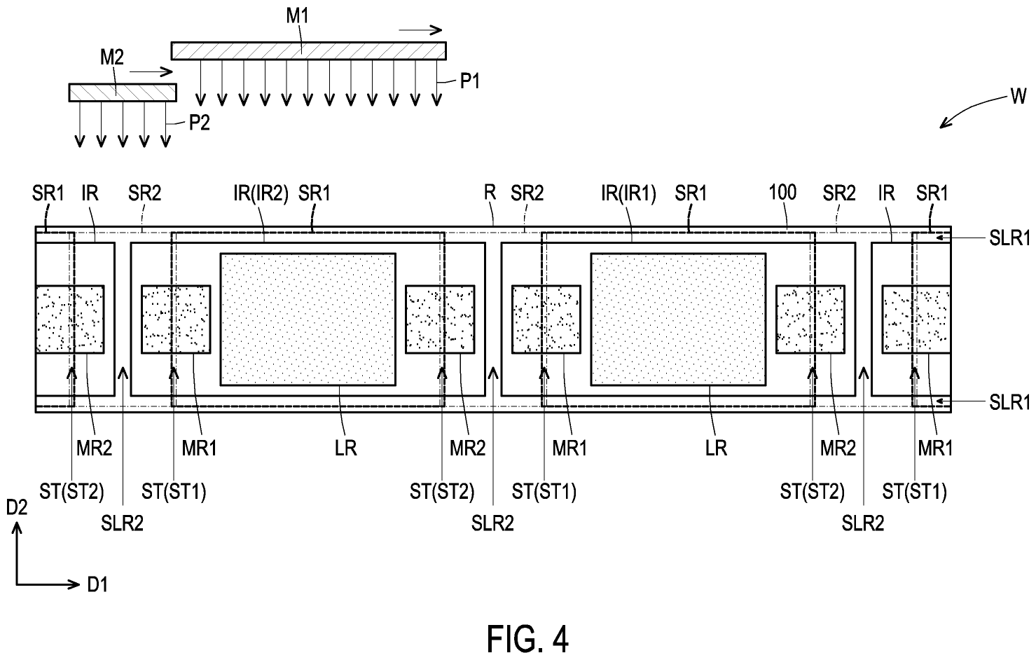

FIG. 1 is a schematic top view of a wafer according to some embodiments of the disclosure. FIG. 2 is a schematic view of an exposure process according to some embodiments of the disclosure. FIG. 3 is a schematic view of an exposure process according to other embodiments of the disclosure. FIG. 4 is a schematic view of an exposure process according to other embodiments of the disclosure. A wafer W in FIG. 2 to FIG. 4 is an enlarged view of the wafer W in a region R depicted in FIG. 1. Some components shown in FIG. 2 to FIG. 4 are omitted in FIG. 1 to clearly illustrate the arrangement relationship among the components depicted in FIG. 1.

With reference to FIG. 1 and FIG. 2, the wafer W is provided. In some embodiments, the wafer W may be a semiconductor wafer, e.g., a silicon wafer. The wafer W includes a plurality of interposer regions IR. In some embodiments, the interposer regions IR may be regions where the wafer W is predetermined to be scribed into interposers (e.g., silicon (Si) interposers).

Each of the interposer regions IR includes a logic chip region LR, a memory chip region MR1, and a memory chip region MR2. The logic chip region LR is located between the memory chip region MR1 and the memory chip region MR2. In some embodiments, the logic chip region LR may be a region of the interposer for carrying a logic chip and to be electrically connected to the logic chip. In some embodiments, the logic chip is, for instance, a system-on-chip (SoC). In some embodiments, the memory chip regions MR1 and MR2 may be regions of the interposer for carrying a memory chip and to be electrically connected to the memory chip. In some embodiments, the memory chip is, for instance, a high bandwidth memory (HBM).

The wafer W may further include a plurality of scribed line regions SLR1 and a plurality of scribed line regions SLR2. The scribed line regions SLR1 may extend in a direction D1 and may be arranged in a direction D2. The scribed line regions SLR2 may extend in the direction D2 and may be arranged in the direction D1. The direction D1 may intersect the direction D2. In some embodiments, the direction D1 may be perpendicular to the direction D2. The first scribed line regions SLR1 may intersect the second scribed line regions SLR2. The scribed line regions SLR1 and the scribed line regions SLR2 may define the interposer regions IR.

With reference to FIG. 2, a photoresist layer 100 is formed on the wafer W. In some embodiments, a method of forming the photoresist layer 100 is, for instance, a spin coating method.

A plurality of exposure processes P1 are performed on the photoresist layer 100 by applying a photomask M1, so as to form a plurality of shot regions SR1 in the photoresist layer 100. In addition, a plurality of exposure processes P2 are performed on the photoresist layer 100 by applying a photomask M2, so as to form a plurality of shot regions SR2 in the photoresist layer 100. In some embodiments, the exposure processes P1 may be performed on the photoresist layer 100 by applying the photomask M1 first, followed by performing the exposure processes P2 on the photoresist layer 100 by applying the photomask M2, which should however not be construed as a limitation in the disclosure. In other embodiments, the exposure processes P2 may be performed on the photoresist layer 100 by applying the photomask M2 first, followed by performing the exposure processes P1 on the photoresist layer 100 by applying the photomask M1. In some embodiments, patterns on the photomask M1 may be different from patterns on the photomask M2.

The shot regions SR1 and the shot regions SR2 are alternately arranged in the direction D1. The shot regions SR1 and the shot regions SR2 are overlapped to form a plurality of stitching regions ST. Each of the stitching regions ST is not located in the logic chip region LR. Since the stitching regions ST are not located in the logic chip regions LR with complex circuit patterns, a process window of the stitching process may be effectively improved.

In some embodiments, the logic chip region LR in each of the interposer regions IR may be exclusively located in a corresponding shot region SR1 of the shot regions SR1. That is, the logic chip region LR in the interposer region IR may not be located in the shot region SR2. In some embodiments, the memory chip region MR1 in each of the interposer regions IR may be located in a corresponding shot region SR2 of the shot regions SR2. In some embodiments, the memory chip region MR2 in each of the interposer regions IR may be located in the corresponding shot region SR2.

In some embodiments, each of the shot regions SR1 may be overlapped with the logic chip region LR in the corresponding interposer region IR. In some embodiments, each of the shot regions SR2 may be overlapped with the memory chip region MR1 in one of two adjacent interposer regions IR (e.g., an interposer region IR1) and the memory chip region MR2 in the other of the two adjacent interposer regions IR (e.g., an interposer region IR2). In some embodiments, each of the shot regions SR1 may be overlapped with a corresponding scribed line region SLR1 of the scribed line regions SLR1. In some embodiments, each of the shot regions SR2 may be overlapped with the corresponding scribed line region SLR1 and a corresponding scribed line region SLR2 of the scribed line regions SLR2.

In some embodiments, each of the interposer regions IR may include two of the stitching regions ST. In some embodiments, one of the two stitching regions ST (e.g., a stitching region ST1) may be located between the logic chip region LR and the memory chip region MR1 in the corresponding interposer region IR. In some embodiments, the other of the two stitching regions ST (e.g., a stitching region ST2) may be located between the logic chip region LR and the memory chip region MR2 in the corresponding interposer region IR.

In other embodiments, as shown in FIG. 3 and FIG. 4, the memory chip region MR1 in each of the interposer regions IR may be further located in the corresponding shot region SR1, and the memory chip region MR2 in each of the interposer regions IR may be further located in the corresponding shot region SR1. In other embodiments, as shown in FIG. 3 and FIG. 4, each of the shot regions SR1 may be overlapped with the memory chip region MR1 and the memory chip region MR2 in the corresponding interposer region IR.

In other embodiments, as shown in FIG. 3 and FIG. 4, one of the two stitching regions ST (e.g., the stitching region ST1) may be overlapped with the memory chip region MR1 in the corresponding interposer region IR, and the other of the two stitching regions ST (e.g., the stitching region ST2) may be overlapped with the memory chip region MR2 in the corresponding interposer region IR.

In the embodiment illustrated in FIG. 2, the photomask M1 includes patterns for forming a circuit in the logic chip region LR, and the photomask M2 includes patterns for forming a circuit in the memory chip region MR1 and patterns for forming a circuit in the memory chip region MR2. In the embodiments illustrated in FIG. 3 and FIG. 4, the photomask M1 includes patterns for forming a circuit in the logic chip region LR, patterns for forming a circuit in the memory chip region MR1, and patterns for forming a circuit in the memory chip region MR2, and the photomask M2 includes patterns for forming a circuit in the memory chip region MR1 and patterns for forming a circuit in the memory chip region MR2.

In some embodiments, as shown in FIG. 2 and FIG. 3, a size of each of the shot regions SR1 (e.g., an area occupied by each of the shot regions SR1) may be equal to a size of each of the shot regions SR2 (e.g., an area occupied by each of the shot regions SR2), which should however not be construed as a limitation in the disclosure. In some embodiments, as shown in FIG. 2 and FIG. 3, the shot region SR1 may be overlapped with about half of the interposer region IR1, and the shot region SR2 may be overlapped with about a quarter of the interposer region IR1 and about a quarter of the interposer region IR2. In other embodiments, as shown in FIG. 4, the size of each of the shot regions SR1 (e.g., the area occupied by each of the shot regions SR1) may be greater than the size of each of the shot regions SR2 (e.g., (e.g., the area occupied by each of the shot regions SR2).

Based on one or more of the embodiments provided above, in the stitching method for the exposure process, since the stitching regions ST are not located in the logic chip regions LR with the complex circuit patterns, the process window of the stitching process may be effectively improved. As such, after the development process is performed on the photoresist layer 100, the anticipated photoresist pattern may be obtained.

To sum up, in the stitching method for the exposure process as provided in one or more embodiments of the disclosure, the process window of the stitching process may be effectively improved. As such, the anticipated photoresist pattern may be obtained.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A stitching method for an exposure process, the stitching method comprising:
providing a wafer, wherein the wafer comprises a plurality of interposer regions, each of the interposer regions comprises a logic chip region, a first memory chip region, and a second memory chip region, and the logic chip region is located between the first memory chip region and the second memory chip region;
forming a photoresist layer on the wafer;
performing a plurality of first exposure processes on the photoresist layer by applying a first photomask to form a plurality of first shot regions in the photoresist layer; and
performing a plurality of second exposure processes on the photoresist layer by applying a second photomask to form a plurality of second shot regions in the photoresist layer, wherein
the first shot regions and the second shot regions are alternately arranged in a first direction,
the first shot regions and the second shot regions are overlapped to form a plurality of stitching regions, and
each of the stitching regions is not located in the logic chip region.

2. The stitching method as recited in claim 1, wherein the logic chip region in each of the interposer regions is exclusively located in a corresponding first shot region of the first shot regions.

3. The stitching method as recited in claim 2, wherein a size of each of the first shot regions is equal to or greater than a size of each of the second shot regions.

4. The stitching method as recited in claim 2, wherein the first memory chip region in each of the interposer regions is located in a corresponding second shot region of the second shot regions.

5. The stitching method as recited in claim 4, wherein the first memory chip region in each of the interposer regions is further located in a corresponding first shot region of the first shot regions.

6. The stitching method as recited in claim 2, wherein the second memory chip region in each of the interposer regions is located in a corresponding second shot region of the second shot regions.

7. The stitching method as recited in claim 6, wherein the second memory chip region in each of the interposer regions is further located in a corresponding first shot region of the first shot regions.

8. The stitching method as recited in claim 1, wherein each of the first shot regions is overlapped with the logic chip region in a corresponding interposer region of the interposer regions.

9. The stitching method as recited in claim 8, wherein the each of the first shot region is further overlapped with the first memory chip region and the second memory chip region in the corresponding interposer region.

10. The stitching method as recited in claim 8, wherein each of the second shot regions is overlapped with the first memory chip region in one of two adjacent interposer regions of the interposer regions and the second memory chip region in the other of the two adjacent interposer regions.

11. The stitching method as recited in claim 1, wherein two of the stitching regions are located in each of the interposer regions.

12. The stitching method as recited in claim 11, wherein one of the two stitching regions is located between the logic chip region and the first memory chip region in a corresponding interposer region of the interposer regions.

13. The stitching method as recited in claim 12, wherein the other of the two stitching regions is located between the logic chip region and the second memory chip region in the corresponding interposer region.

14. The stitching method as recited in claim 11, wherein one of the two stitching regions is overlapped with the first memory chip region in the corresponding interposer region.

15. The stitching method as recited in claim 14, wherein the other of the two stitching regions is overlapped with the second memory chip region in the corresponding interposer region.

16. The stitching method as recited in claim 1, wherein
the wafer further comprises a plurality of first scribed line regions and a plurality of second scribed line regions,
the first scribed line regions extend in a first direction and are arranged in a second direction,
the second scribed line regions extend in the second direction and are arranged in the first direction,
the first direction intersects the second direction, and
the first scribed line regions intersect the second scribed line regions.

17. The stitching method as recited in claim 16, wherein the first scribed line regions and the second scribed line regions define the interposer regions.

18. The stitching method as recited in claim 16, wherein the first direction is perpendicular to the second direction.

19. The stitching method as recited in claim 16, wherein each of the first shot regions is overlapped with a corresponding first scribed line region of the first scribed line regions.

20. The stitching method as recited in claim 19, wherein each of the second shot regions is overlapped with a corresponding first scribed line region of the first scribed line regions and a corresponding second scribed line region of the second scribed line regions.
